(19) United States
(12) Patent Application Publication
(10) Pub. No.: US 2019/0172385 A1
(43) Pub. Date: Jun. 6, 2019

(54) Display device and detecting method for signal from subject using the same

(71) Applicant: InnoLux Corporation, Miao-Li County (TW)

(72) Inventors: Ayumu MORI, Miao-Li County (TW); Kazuto JITSUI, Miao-Li County (TW); Keiko EDO, Miao-Li County (TW)

(21) Appl. No.: 16/018,611

(22) Filed: Jun. 26, 2018

Related U.S. Application Data
(60) Provisional application No. 62/593,279, filed on Dec. 1, 2017.

(51) Int. Cl. G09G 3/20; G09G 3/34; G09G 3/30; H01L 25/16

(52) U.S. Cl. CPC G09G 3/2074; G09G 3/3413; G09G 2360/147; H01L 25/167; G09G 3/30

(57) ABSTRACT

The present disclosure provides a method for sensing a signal from a subject, including the following steps: providing a display device including first and second blocks, wherein the first and second block respectively include at least one light sensor and plural sub-pixels, one of the at least one light sensor corresponds to at least two adjacent of the sub-pixels; and detecting a signal from a subject, wherein one of the sub-pixels of the first block and the one of the at least one light sensor of the first block are in enabled status and the second block is in disabled status in a first time period, and one of the sub-pixels of the second block and the one of the at least one light sensor of the second block are in enabled status and the first block is in disabled status in a second time period.

### CROSS REFERENCE TO RELATED APPLICATION

This application claims the benefit of filing date of U.S. Provisional Application Ser. No. 62/593,279 filed Dec. 1, 2017 under 35 USC § 119(e)(1).

### BACKGROUND

### 1. Field

The present disclosure relates to an electronic apparatus and, more particularly, to a display apparatus with light sensors.

### 2. Description of Related Art

With the continuous advancement of technologies related to electronic devices, all the electronic devices are now developed toward compactness, thinness, and lightness. For example, thin display devices are the mainstream display devices on the market.

Nowadays, the display devices are required to have not only the display function but also other functions such as touch or identification functions. In addition, for a purpose that the display devices have higher display-to-body ratio, outer sensors have to be designed to be embedded into display regions of the display devices. Hence, how to integrate a sensor into the display device without reducing the accuracy or the resolution of the sensor and also without affecting the functions of the display device is one issue that may be solved.

### SUMMARY

The present disclosure provides a method for sensing a signal from a subject, comprising the following steps: providing a display device comprising a first block and a second block, wherein the first block and the second block respectively comprise at least one light sensor and plural sub-pixels, one of the at least one light sensor corresponds to at least two adjacent of the plural sub-pixels; and detecting a signal from a subject, wherein one of the plural sub-pixels of the first block and the one of the at least one light sensor of the first block are in enabled status and the second block is in disabled status in a first time period, and one of the plural sub-pixels of the second block and the one of the at least one light sensor of the second block are in enabled status and the first block is in disabled status in a second time period.

The present disclosure also provides another for sensing a signal from a subject, comprising the following steps: providing a display device comprising a display region, wherein plural sub-pixels and plural light sensors are disposed on the display region, and plural color units are respectively disposed on the plural light sensors; and detecting a signal from a subject, wherein all the plural light sensors are in enabled status and one of the plural sub-pixels are in enabled status.

The present disclosure further provides a display device comprising a display region, wherein the display device comprises: plural sub-pixels disposed on the display region; and plural light sensors disposed on the display region, wherein one of the plural light sensors corresponds to at least two adjacent of the plural sub-pixels.

Other novel features of the disclosure will become more apparent from the following detailed description when taken in conjunction with the accompanying drawings.

### BRIEF DESCRIPTION OF THE DRAWINGS

FIG. 1 is a perspective view showing a display device according to Embodiment 1 of the present disclosure.

FIG. 2A to FIG. 2D are diagrams illustrating a method for sensing a signal from a subject by a display device according to Embodiment 2 of the present disclosure.

FIG. 3 is a signal diagram illustrating operations of sub-pixels in a display device according to Embodiment 2 of the present disclosure.

FIG. 4A to 4F are diagrams illustrating a method for sensing a signal from a subject by a display device according to different aspects of the present disclosure.

FIG. 5A and FIG. 5B are diagrams illustrating a pixel and a light sensor which are in enabled status in one time period according to different aspects of the present disclosure.

FIG. 6A to FIG. 6F are diagrams illustrating the arrangements of sub-pixels and light sensors in a display device according to different aspects of the present disclosure.

FIG. 7A to FIG. 7D are diagrams illustrating a method for sensing a signal from a subject by a display device according to Embodiment 3 of the present disclosure.

FIG. 8 is a signal diagram illustrating operations of sub-pixels in a display device according to Embodiment 3 of the present disclosure.

FIG. 9A is diagram illustrating sub-pixels and light sensors in a display device according to Embodiment 4 of the present disclosure.

FIG. 9B is a diagram illustrating at least part of sub-pixels and light sensors which are in enabled status in a display device according to Embodiment 4 of the present disclosure.

FIG. 10A to FIG. 10C are diagrams illustrating sub-pixels and light sensors in a display device according to different aspects of the present disclosure.

### DETAILED DESCRIPTION OF EMBODIMENT

The following embodiments when read with the accompanying drawings are made to clearly exhibit the above-mentioned and other technical contents, features and/or effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

Furthermore, the terms recited in the specification and the claims such as “above”, “over”, or “on” are intended not only directly contact with the other element, but also intended indirectly contact with the other element. Similarly, the terms recited in the specification and the claims such as “below”, or “under” are intended not only directly contact with the other element but also intended indirectly contact with the other element.

In addition, the features in different embodiments of the present disclosure can be mixed to form another embodiment.

### Embodiment 1

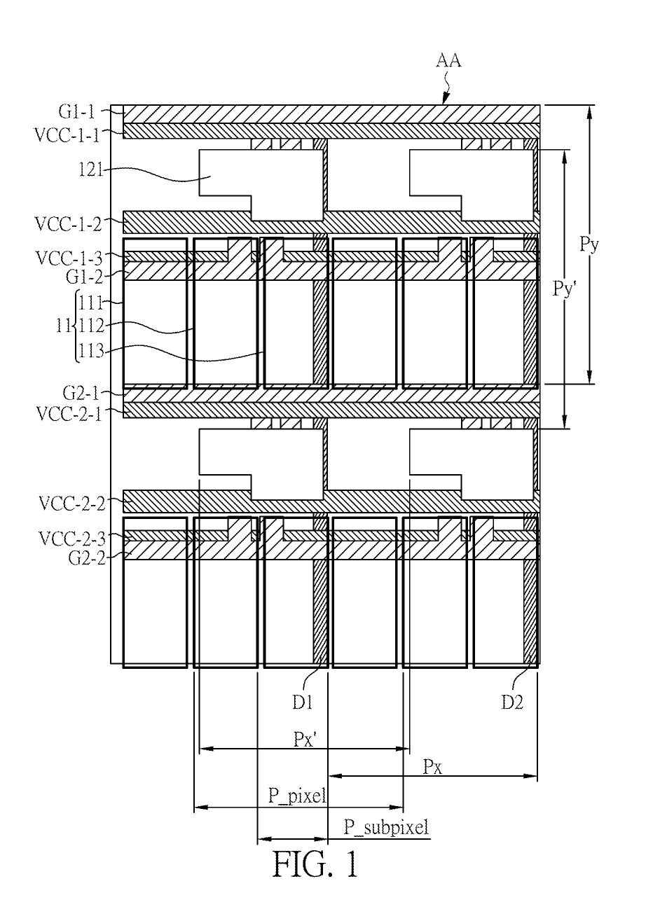

FIG. 1 is a perspective view showing a display device according to the present embodiment.

The display device of the present embodiment comprises a display region AA wherein the display device comprises: plural pixels 11 comprising plural sub-pixels 111, 112, 113 disposed on the display region AA; and plural light sensors 121 disposed on the display region AA, wherein one of the plural light sensors 121 corresponds to at least two adjacent of the plural sub-pixels 111, 112, 113. In the present embodiment, the one of the plural light sensors 121 corresponds to two adjacent sub-pixels 112, 113; but the present disclosure is not limited thereto. Herein, a sub-pixel pitch P_subpixel may be defined by a distance from the same edges of one sub-pixel to another sub-pixel adjacent thereto. For example, as indicated in FIG. 1, the sub-pixel pitch P_subpixel is a distance from the right edge of the sub-pixel 112 to the right edge of the sub-pixel 113. The pixel pitch P-pixel may be defined by a distance from the same edges of two sub-pixels, wherein one of the two sub-pixels has a color, the other one of the two sub-pixels is a sub-pixel having the same color which is closet to the one of the two sub-pixels. For example, as indicated in FIG. 1, the pixel pith P_pixel is a distance from the left edge of the sub-pixel 112 having green color to the left edge of another sub-pixel 112 which is a green color sub-pixel closest to the sub-pixel 112.

The display device of the present embodiment further comprises: first scan lines G1-1, G1-2, second scan lines G2-1, G2-2, power lines VCC-1-1, VCC-1-2, VCC-1-3, VCC-2-1, VCC-2-2, VCC-2-3, a first data line D1, a second data line D2, transistors (not shown in the figure) and capacitors (not shown in the figure). Herein, the distance Py from the first scan line G1-1 to the second scan line G2-1 and the distance Px from the first data line D1 to the second data line D2 can define the sensing pitch of the light sensor 121. However, the present disclosure is not limited thereto. In another embodiment of the present disclosure, the sensing pitch of the light sensor 121 can be defined by the distances Py′ and Px′ from the same edges of two adjacent light sensors 121.

In general, the required sensing pitch for the sensing and the required pixel pith for the display, which can be defined by pixels per inch (ppi), are independent. When anyone of the light sensors 121 detects a signal from a subject, two adjacent sensors 121 disposed in a sensing pitch around 50 μm (about 1/10 of fingerprint pattern) (about 500 ppi) can exhibit good resolution. On the other hand, the require pixel pitch P_pixel between two adjacent pixels 11 including sub-pixels 111, 112, 113 is various, and the pixel pith around 500 ppi is usually high enough. Hence, if the sensing pith of the light sensors 121 is set to be equal to the sub-pixel pitch of the two adjacent sub-pixels 111, 112, 113, no benefit for the display device embedded with light sensors 121 can be generated. Therefore, in the present embodiment, one of the plural light sensors 121 corresponds to at least two adjacent sub-pixels 111, 112, 113, so the sensing pith of the light sensors 121 is set to be as multiple of the sub-pixel pith of two adjacent sub-pixels 111, 112, 113. Thus, the preparation process of the light sensors 121 can be simplified.

Hereinafter, an example of a circuit for the light sensors 121 which is a photodiode is exemplified. However, the present disclosure is not limited thereto, and the circuit for the light sensors 121 can be modified according to the need.

In one example of the present disclosure, the power line VCC-1-1 electrically connects to a diode cathode of the light sensor 121, the power line VCC-1-2 electrically connects to a diode anode of the light sensor 121, the power line VCC-1-3 provides a source voltage, the scan line G1-1 provides a scan signal, and the scan line G1-2 provides a reset signal. When light irradiates into the light sensors 121, a diode leakage current (from diode cathode to the diode anode) is increased, the anode capacity is charged up and increased over the threshold voltage of the connected TFT gate, which has the power line VCC-1-3 as source voltage. Next, the scan line G1-1 is on, and the first data line D1 reads out the photo signal from the VCC-1-3 according to the TFT gate voltage by anode capacity. Then, the scan line G1-2 is on, and the anode capacity charges are released.

In another embodiment of the present disclosure, the display device may not comprise the second scan lines G2-1, G2-2.

### Embodiment 2

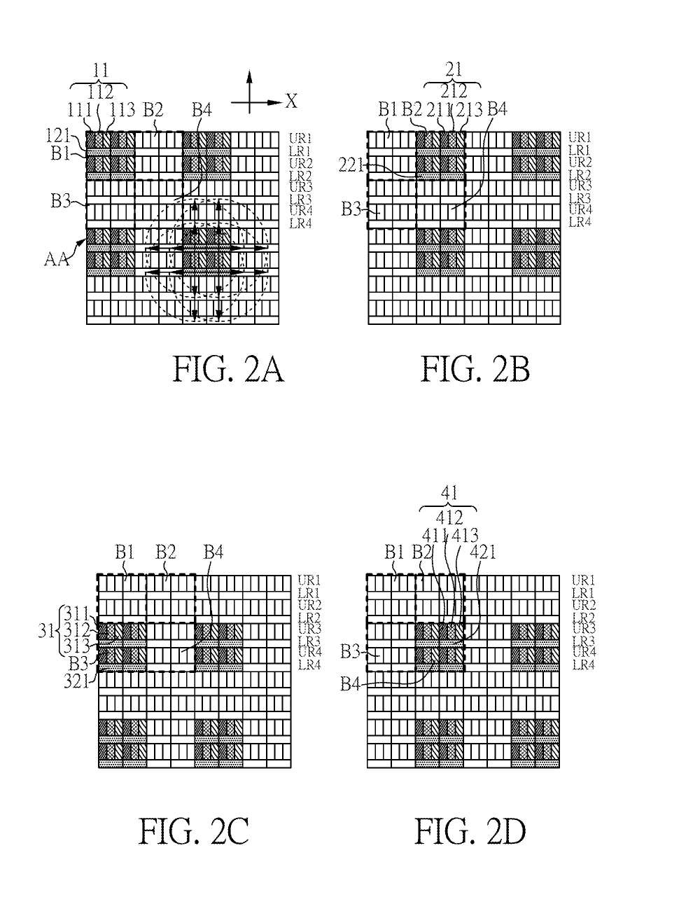

FIG. 2A to FIG. 2D are diagrams illustrating a method for detecting a signal from a subject by a display device according to the present embodiment, wherein the sub-pixels and the light sensors which are in enabled status are present with filling patterns, and the sub-pixels and the light sensors which are in disabled status are present with blank.

As shown in FIG. 2A and FIG. 2B, the display device of the present embodiment comprises a display region AA, wherein plural pixels 11, 21, 31, 41 comprising plural sub-pixels 111, 112, 113, 211, 212, 213, 311, 312, 313, 411, 412, 413 and plural light sensors 121, 221, 321, 421 are disposed on the display region AA. Herein, the sub-pixels 111, 211, 311, 411 have the same color and are red sub-pixels, the sub-pixels 112, 212, 312, 412 have the same color and are green sub-pixels, and the sub-pixels 113, 213, 313, 413 have the same color and are blue sub-pixels. However, the present disclosure is not limited thereto.

In the display device of the present embodiment, each light sensor 121, 221, 321, 421 is embedded in each pixel 11, 21, 31, 41, and the light sensors 121, 221, 321, 421 can be controlled together with the sub-pixels 111, 112, 113, 211, 212, 213, 311, 312, 313, 411, 412, 413 in the pixels 11, 21, 31, 41 when anyone of the light sensors 121, 221, 321, 421 detects a signal from a subject.

As shown in FIG. 2A to FIG. 2D, when anyone of the light sensors 121, 221, 321, 421 detects a signal from a subject, the sub-pixels 111, 112, 113, 211, 212, 213, 311, 312, 313, 411, 412, 413 and the light sensors 121, 221, 321, 421 are divided into plural blocks, the blocks comprises at least one first block B1 and at least one second block B2 arranged in a predetermined pattern. In the present embodiment, the blocks further comprises at least one third block B3 and at least one fourth block B4, and the first block B1, the second block B2, the third block B3 and the fourth block B4 are arranged in a predetermined pattern. In the present embodiment, the first block B1, the second block B2, the third block B3 and the fourth block B4 are arranged in a 2×2 array. However, the present disclosure is not limited thereto.

The first block B1 comprises the sub-pixels 111, 112, 113 and the light sensor 121 adjacent to the sub-pixels 111, 112, 113, the second block B2 comprises the sub-pixels 211, 212, 213 and the light sensor 221 adjacent to the sub-pixels 211, 212, 213, the third block B3 comprises the sub-pixels 311, 312, 313 and the light sensor 321 adjacent to the sub-pixels 311, 312, 313, and the fourth block B4 comprises the sub-pixels 411, 412, 413 and the light sensor 421 adjacent to the sub-pixels 411, 412, 413. In the present embodiment, the first block B1 comprises four pixels 11 and four light sensors 121 and each pixel 11 is adjacent to one of the light sensors 121. If one pixel (for example, the pixel 11) and one light sensor (for example, the light sensor 121) is considered as an unit, the first block B1 is constituted by four units arranged in a 2×2 array. The features of the second block B2, the third block B3 and the fourth block B4 are similar to the feature of the first block B1, and are not illustrated again. However, the present disclosure is not limited thereto.

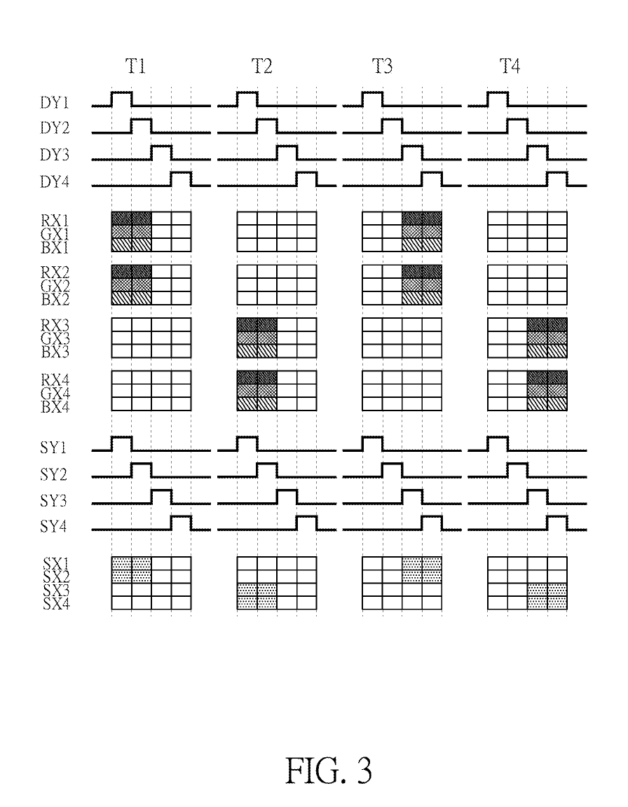

FIG. 3 is a signal diagram illustrating operations of sub-pixels in a display device according the present embodiment. FIG. 3 shows the disabling and enabling of the sub-pixels 111, 112, 113, 211, 212, 213, 311, 312, 313, 411, 412, 413 and the light sensors 121, 221, 321, 421 comprised in one first block B1, one second block B2, one third block B3 and one fourth block B4 shown in FIG. 2A to FIG. 2D, and also shows the signal applied to the sub-pixels 111, 112, 113, 211, 212, 213, 311, 312, 313, 411, 412, 413 and the light sensors 121, 221, 321, 421 shown in FIG. 2A to FIG. 2D, wherein the sub-pixels and the light sensors which are in enabled status are present with filling patterns, and the sub-pixels and the light sensors which are in disabled status are present with blank. The rows RX1, GX1, BX1, RX2, GX2, BX2, RX3, GX3, BX3, RX4, GX4 and BX4 shown in FIG. 3 refers to the sub-pixels 111, 112, 113, 211, 212, 213, 311, 312, 313, 411, 412, 413 shown in FIG. 2A to FIG. 2D, and the rows SX1, SX2, SX3 and SX4 shown in FIG. 3 refers to the light sensors 121, 221, 321, 421 shown in FIG. 2A to FIG. 2D. When one first block B1, one second block B2, one third block B3 and one fourth block B4 shown in FIG. 2A to FIG. 2D together are considered as one group, the rows RX1, GX1, BX1, RX2, GX2, BX2, RX3, GX3, BX3, RX4, GX4 and BX4 shown in FIG. 3 respectively refers to the columns from the left to the right comprised in the one group shown in FIG. 2A to FIG. 2D, and the rows SX1, SX2, SX3 and SX4 shown in FIG. 3 refers to the columns from the left to the right comprised in the one group shown in FIG. 2A to FIG. 2D. In the first time period T1 shown in FIG. 3, DY1 refers to the signal applied to the scan lines to trigger the sub-pixels shown in the first left column of the sub-pixels; in other word, DY1 refers to the signal applied to the scan lines to trigger the sub-pixels shown in the first upper row UR1 of the one group shown in FIG. 2A. In the first time period T1 shown in FIG. 3, DY2 refers to the signal applied to the scan lines to trigger the sub-pixels shown in the second left column of the sub-pixels; in other word, DY2 refers to the signal applied to the scan lines to trigger the sub-pixels shown in the second upper row UR2 of the one group shown in FIG. 2A. In the first time period T1 shown in FIG. 3, DY3 refers to the signal applied to the scan lines to trigger the sub-pixels shown in the third left column of the sub-pixels; in other word, DY3 refers to the signal applied to the scan lines to trigger the sub-pixels shown in the third upper row UR3 of the one group shown in FIG. 2A. And, in the first time period T1 shown in FIG. 3, DY4 refers to the signal applied to the scan lines to trigger the sub-pixels shown in the first right column of the sub-pixels; in other word, DY4 refers to the signal applied to the scan lines to trigger the sub-pixels shown in the fourth upper row UR4 of the one group shown in FIG. 2A. In addition, in the first time period T1 show in FIG. 3, SY1 refers to the signal applied to the scan lines to trigger the light sensor shown in the first left column of the light sensors; in other word, SY1 refers to the signal applied to the scan lines to trigger the light sensors shown in the first lower row LR1 of the one group shown in FIG. 2A. In the first time period T1 show in FIG. 3, SY2 refers to the signal applied to the scan lines to trigger the light sensor shown in the second left column of the light sensors; in other word, SY2 refers to the signal applied to the scan lines to trigger the light sensors shown in the second lower row LR2 of the one group shown in FIG. 2A. In the first time period T1 show in FIG. 3, SY3 refers to the signal applied to the scan lines to trigger the light sensor shown in the third left column of the light sensors; in other word, SY3 refers to the signal applied to the scan lines to trigger the light sensors shown in the third lower row LR3 of the one group shown in FIG. 2A. And, in the first time period T1 show in FIG. 3, SY4 refers to the signal applied to the scan lines to trigger the light sensor shown in the first right column of the light sensors; in other word, SY4 refers to the signal applied to the scan lines to trigger the light sensors shown in the fourth lower row LR4 of the one group shown in FIG. 2A. The signals shown in DY1, DY2, DY3, DY4, SY1, SY2, SY3 and SY4 in the second time period T2, the third time period T3 and the fourth time period T4 are similar to those illustrated for the first time period T1, and the descriptions related thereto are not repeated again. As shown in FIG. 2A to FIG. 2D and FIG. 3, when anyone of the light sensors 121, 221, 321, 421 detects a signal from a subject, the first block B1 is in enabled status and the second block B2 is in disabled status in a first time period T1, and the second block B2 is in enabled status and the first block B1 is in disabled status in a second time period T2. More specifically, in the first time period T1, the first block B1 is in enabled status, and the second block B2, the third block B3 and the fourth block B4 are in disabled status, as shown in FIG. 2A; wherein the sub-pixels 111, 112, 113 of the pixels 11 and the light sensors 121 are in enabled status. In the second time period T2, the second block B2 is in enabled status, and the first block B1, the third block B3 and the fourth block B4 are in disabled status, as shown in FIG. 2B; wherein the sub-pixels 211, 212, 213 of the pixels 21 and the light sensors 221 are in enabled status. In the third time period T3, the third block B3 is in enabled status, and the first block B1, the second block B2 and the fourth block B4 are in disabled status, as shown in FIG. 2C; wherein the sub-pixels 311, 312, 313 of the pixels 31 and the light sensors 321 are in enabled status. In the fourth time period T4, the fourth block B4 is in enabled status, and the first block B1, the second block B2 and the third block B3 are in disabled status, as shown in FIG. 2D; wherein the sub-pixels 411, 412, 413 of the pixels 41 and the light sensors 421 are in enabled status. Herein, the first time period T1, the second time period T2, the third time period T3 and the fourth time period T4 constitute a frame.

When anyone of the light sensors 121, 221, 321, 421 detects a signal from a subject, the sub-pixels 111, 112, 113, 211, 212, 213, 311, 312, 313, 411, 412, 413 and the light sensors 121, 221, 321, 421 are divided into plural blocks including the first block B1, the second block B2, the third block B3 and the fourth block B4. The size of the blocks is set to be larger than an image blur region of the light sensors 121, 221, 321, 421. In other word, the size of the blocks is set to be larger than an optical resolution of the light sensors 121, 221, 321, 421. For example, as shown in FIG. 2A, the circles and the arrows refer to the image blur regions of each light sensor 121 in the first block B1. The distance between two adjacent first blocks B1 is larger than the image blur regions of the light sensors 121. Hence, the reflected light from the sub-pixels 111, 112, 113 which are in enabled status can only be detected by the light sensors 121 which are also in enabled status. No light emits from the second block B2, the third block B3 and the fourth block B4 (i.e. from the sub-pixels 211, 212, 213, 311, 312, 313, 411, 412, 413) which are in disabled status, the light emitting from the first block B1 is not mixed with the light emitting from the second block B2, the third block B3 and the fourth block B4 in the first time period, and thus the image resolution can be maximized as equal to the resolution of the light sensors 121, 221, 321, 421. Therefore, the defocus problem (i.e. the image blur problem) occurred in the display device embedded with light sensors can be solved.

As shown in FIG. 2A to FIG. 2D, the sub-pixels 111, 112, 113, 211, 212, 213, 311, 312, 313, 411, 412, 413 and the light sensors 121, 221, 321, 421 are divided into four blocks including the first block B1, the second block B2, the third block B3 and the fourth block B4, which are arranged in a 2×2 array. In addition, if one pixel (for example, the pixel 11) and one light sensor (for example, the light sensor 121) is considered as an unit, the first block B1, the second block B2, the third block B3 and the fourth block B4 are respectively constituted by four units arranged in a 2×2 array. In the first time period T1, the first block B1 comprises four pixels 11 and four light sensors 121, which are in enabled status. In the second time period T2, the second block B2 comprises four pixels 21 and four light sensors 221 which are in enabled status. In the third time period T3, the third block B3 comprises four pixels 31 and four light sensors 321 which are in enabled status. In the fourth time period T4, the fourth B4 comprises four pixels 41 and four light sensors 421 which are in enabled status. Hence, in the present embodiment, in one time period, the optical resolution of the sensor device (or display device) is 16 pixels size, and the improved sensor resolution become 4 pixels size.

However, the present disclosure is not limited thereto, and the number of the blocks comprised in one group, the shape of the blocks, the number of the sub-pixels comprised in one block, and the number of the light sensors comprised in one block can be varied as long as the following requirement is satisfied.

In the present disclosure, the “group” refers to the minimum repeated pattern when an image displayed on the display device is detected during the period of sensing a signal from a subject. The “group” may also be called as a predetermined pattern. In the present disclosure, the display device may comprise plural groups (predetermined patterns), each group comprises the first block, the second block, etc. The first block refers to the block which is in enabled status in the first time period, and the second block refers to the block which is in enabled status in the second time period.

In the present disclosure, a frame comprises N time periods (comprising the first time period and the second time period), N is an integer ranged from 2 to 50, one of the plural blocks comprising at least one of the plural pixels and at least one of the plural light sensors is in enabled status in one time period of the frame, and the at least one of the plural pixels and the at least one of the plural light sensors in the one of the plural blocks are in enabled status in the one time period of the frame. In addition, a group comprises M blocks (comprising the first block B1 and the second block B2), M is an integer ranged from 2 to 50 and equal to N, and one of the blocks is in enabled status and the rest of the blocks are in disabled status in one time period of the frame. For example, the first block B1 is in enabled status and the rest of the blocks are in disabled status in the first time period while the second block B2 is in enabled status and the rest of the blocks are in disabled status in the second time period.

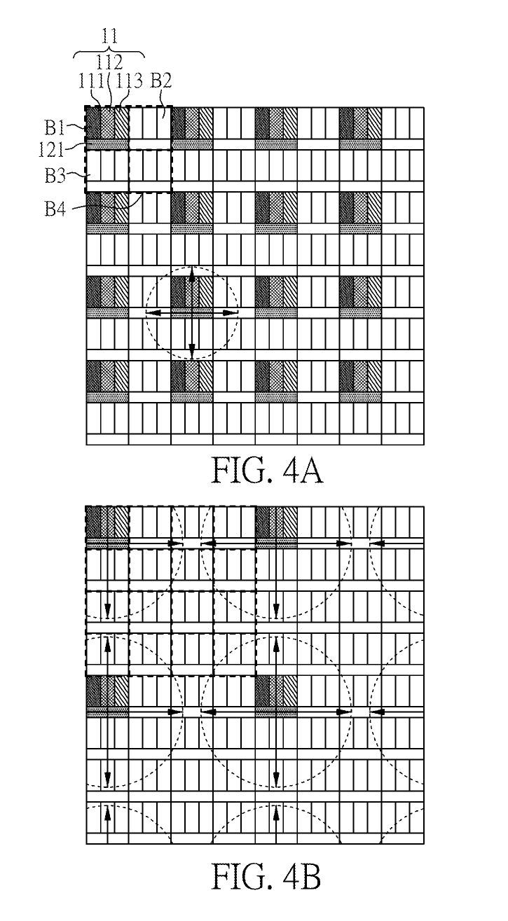

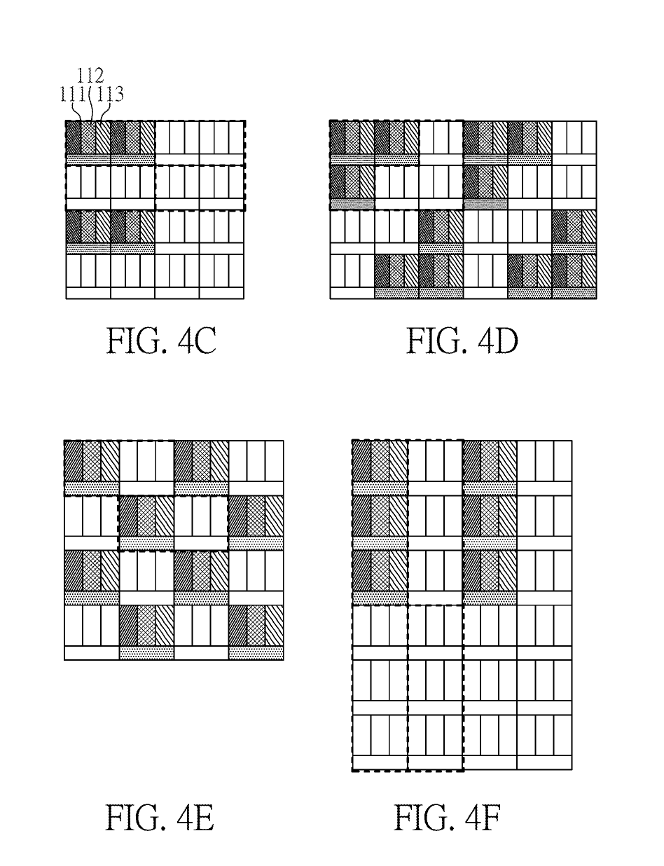

FIG. 4A to 4F are diagrams illustrating a method for sensing a signal from a subject in a first time period by a display device in different aspects of the present disclosure.

As shown in FIG. 4A, four blocks (including the first block B1, the second block B2, the third block B3 and the fourth block B4) are respectively constituted by one pixel and one light sensor. For example, the first block B1 comprises a pixel 11 including the sub-pixels 111, 112, 113 and a light sensor 121. The four blocks constitute a group and are arranged in a 2×2 array. When anyone of the light sensors detects a signal from a subject, the sub-pixels and the light sensors are scanned by a frame comprising four time periods. One of the four blocks (i.e. the first block B1) is in enabled status and the rest of the blocks are in disabled status in the first time period, and one pixel and one light sensor comprised in the enabled block (i.e. the first block B1) are also in enabled status in the first time period. In addition, another one of the four blocks (i.e. the second block B2) is in enabled status and the rest of the blocks are in disabled status in the second time period, and one pixel and one light sensor comprised in the enabled block (i.e. the second block B2) are also in enabled status in the second time period. Hence, in the present embodiment, in one time period, if the optical resolution of the sensor device (or display device) is equivalent to 4 pixels size, and the improved sensor resolution become 1 pixels size.

The aspect shown in FIG. 4B is similar to that shown in FIG. 4A, except that a group comprises 16 blocks, and the sub-pixels and the light sensors are scanned by a frame comprising 16 time periods. The scanning method is similar to those stated above, and is not illustrated again. Hence, in the present embodiment, in one time period, if the optical resolution of the sensor device (or display device) is equivalent to 16 pixels size, and the improved sensor resolution become 1 pixels size.

The aspect shown in FIG. 4C is similar to that shown in FIG. 4A, except that two pixels and two light sensors are comprised in one block, a group comprises four blocks, and the sub-pixels and the light sensors are scanned by a frame comprising four time period. The scanning method is similar to those stated above, and is not illustrated again.

The aspect shown in FIG. 4D is similar to that shown in FIG. 4A, except that three pixels and three light sensors arranged in an uppercase L shape are comprised in one block, a group comprises two blocks, and the sub-pixels and the light sensors are scanned by a frame comprising two time periods. The scanning method is similar to those stated above, and is not illustrated again.

The aspect shown in FIG. 4E is similar to that shown in FIG. 4A, except that a group comprises two blocks, two pixel and two light sensor are comprised in one block, and the sub-pixels and the light sensors are scanned by a frame comprising two time periods. Two pixels and two light sensors that are diagonal are considered as a unit, the block is constituted by two units arranged in a diagonal pattern. The scanning method is similar to those stated above, and is not illustrated again.

The aspect shown in FIG. 4F is similar to that shown in FIG. 4A, except that three pixels and three light sensors aligned in a line are comprised in one block, a group comprises four blocks, and the sub-pixels and the light sensors are scanned by a frame comprising four time periods. The scanning method is similar to those stated above, and is not illustrated again.

In the aspects shown in FIG. 2A to FIG. 2D and FIG. 4A to FIG. 4F, when one of the blocks is in enabled status in one time period of the frame, the pixel(s) including the sub-pixels and the light sensor(s) comprised therein are in enabled status, and the enabled pixel(s) including the sub-pixels is adjacent to the enabled light sensor(s). For example, as shown in FIG. 2A and FIG. 2B, the sub-pixels 111, 112, 113 and the light sensors 121 comprised in the first block B1 are in enabled status and adjacent in the first time period T1, and the sub-pixels 211, 212, 213 and the light sensors 221 comprised in the second block B2 are in enabled status and adjacent in the second time period T2. However, the present disclosure is not limited thereto, as long as the enabled pixel(s) including the sub-pixels and the enabled light sensor(s) are comprised in the enabled block.

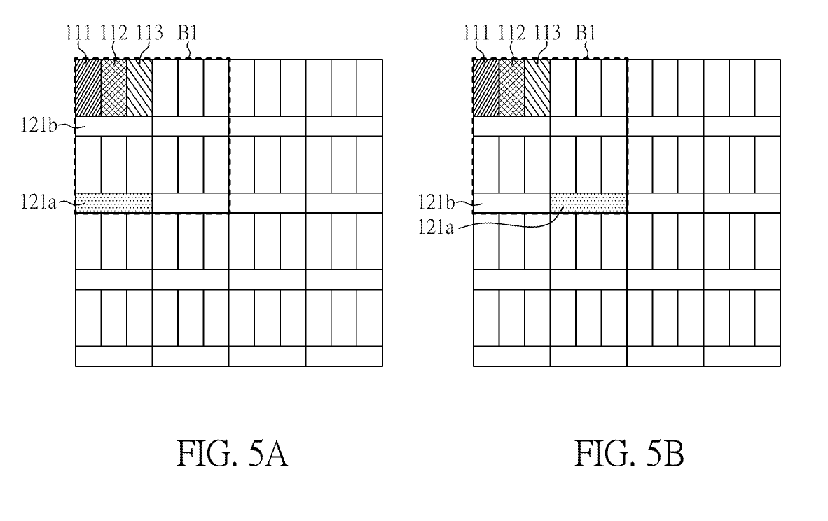

FIG. 5A and FIG. 5B are diagrams illustrating a pixel and a light sensor which are in enabled status in one time period according to different aspects of the present disclosure. For example, in a first time period, the first block B1 is in enabled status, the first block B1 comprises plural sub-pixels 111, 112, 113 and plural light sensors 121a, 121b, and a light sensor 121b which is in disabled status is disposed between the sub-pixels 111, 112, 113 and the light sensor 121a which are in enabled status.

In the aspects shown in FIG. 2A to FIG. 2D and FIG. 4A to FIG. 5B, one light sensor is disposed adjacent to one pixel, which means one light sensor is adjacent corresponds to three sub-pixels. However, the present disclosure is not limited thereto.

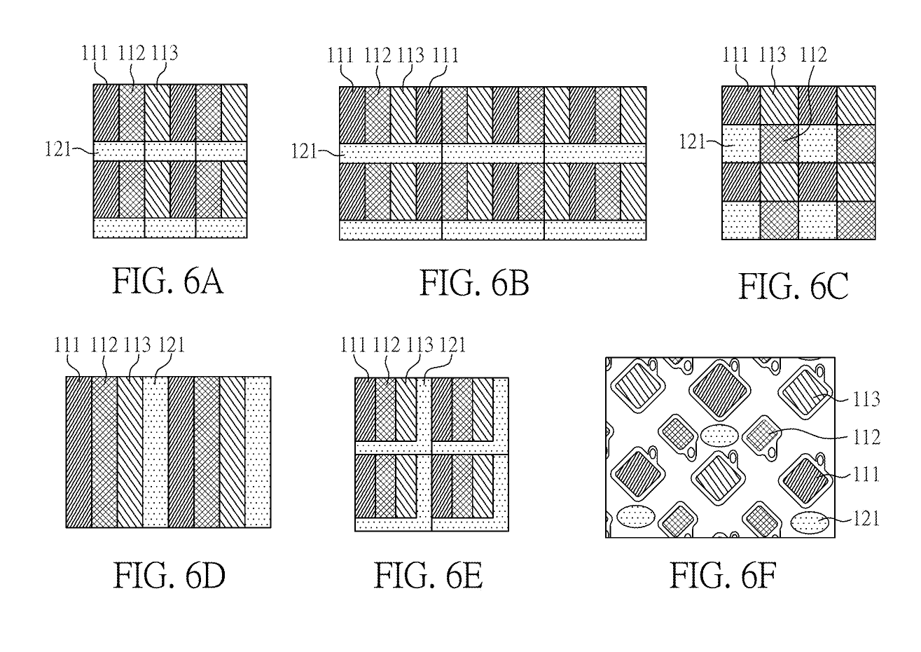

FIG. 6A to FIG. 6F are diagrams illustrating the arrangements of sub-pixels and light sensors in a display device according to different aspects of the present disclosure.

As shown in FIG. 6A, one light sensor 121 is adjacent and corresponds to two sub-pixels 111, 112. As shown in FIG. 6B, one light sensor 121 is adjacent and corresponds to four sub-pixels including two sub-pixels 111, one sub-pixel 112 and one sub-pixel 113. As shown in FIG. 6C, one light sensor 121 is adjacent and corresponds to three sub-pixels 111, 112, 113, and light sensor 121 and three sub-pixels 111, 112, 113 are arranged in a 2×2 array. As shown in FIG. 6D, one light sensor 121 corresponds to one pixel including the sub-pixels 111, 112, 113 and is adjacent to one sub-pixel 113. As shown in FIG. 6E, one light sensor 121 is adjacent and corresponds to three sub-pixels 111, 112, 113 and the light sensors 121 as an uppercase L shape. As shown in FIG. 6F, the sub-pixels 111, 112, 113 can be present in a diamond pattern, and the light sensors 121 can be disposed in a predetermined interval. For example, two sub-pixels are disposed between two light sensors 121 as shown in FIG. 6F. In addition, the colors or the shapes of the light sensors 121 and the sub-pixels 111, 112, 113 are not limited to those shown in FIG. 6F. In another embodiment, at least two of the sub-pixels 111, 112, 113 may have the same color. In further another embodiment, it may have another sub-pixel with its color different from the sub-pixels 111, 112, 113. However, in the present disclosure, the relative position of the light sensor and the sub-pixels and the shape or the arrangement of the light sensor is not limited to the aspects shown above.

### Embodiment 3

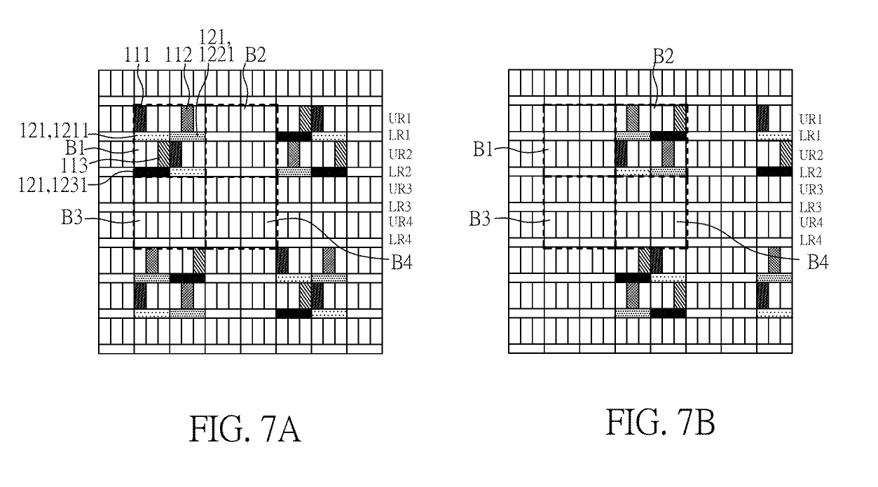

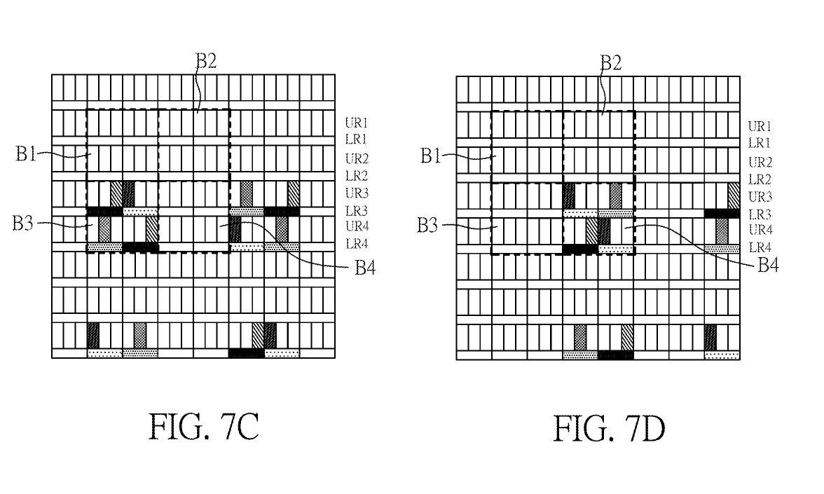

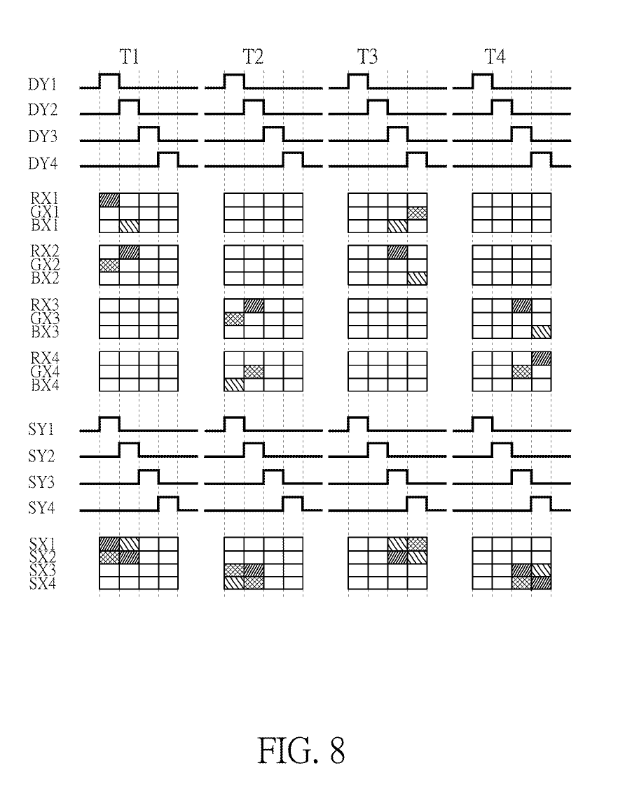

FIG. 7A to FIG. 7D are diagrams illustrating a method for detecting a signal from a subject by a display device according to the present embodiment. FIG. 8 is a signal diagram illustrating operations of sub-pixels in a display device according the present embodiment. FIG. 8 shows the disabling and enabling of the sub-pixels 111, 112, 113, 211, 212, 213, 311, 312, 313, 411, 412, 413 and the light sensors 121, 221, 321, 421 comprised in one first block B1, one second block B2, one third block B3 and one fourth block B4 shown in FIG. 7A to FIG. 7D, and also shows the signal applied to the sub-pixels 111, 112, 113, 211, 212, 213, 311, 312, 313, 411, 412, 413 and the light sensors 121, 221, 321, 421 shown in FIG. 7A to FIG. 7D, wherein the sub-pixels and the light sensors which are in enabled status are present with filling patterns, and the sub-pixels and the light sensors which are in disabled status are present with blank. The rows RX1, GX1, BX1, RX2, GX2, BX2, RX3, GX3, BX3, RX4, GX4 and BX4 shown in FIG. 8 refers to the sub-pixels 111, 112, 113, 211, 212, 213, 311, 312, 313, 411, 412, 413 shown in FIG. 7A to FIG. 7D, and the rows SX1, SX2, SX3 and SX4 shown in FIG. 8 refers to the light sensors 121, 221, 321, 421 shown in FIG. 7A to FIG. 7D. When one first block B1, one second block B2, one third block B3 and one fourth block B4 shown in FIG. 7A to FIG. 7D together are considered as one group, the rows RX1, GX1, BX1, RX2, GX2, BX2, RX3, GX3, BX3, RX4, GX4 and BX4 shown in FIG. 8 respectively refers to the columns from the left to the right comprised in the one group shown in FIG. 7A to FIG. 7D, and the rows SX1, SX2, SX3 and SX4 shown in FIG. 8 refers to the columns from the left to the right comprised in the one group shown in FIG. 7A to FIG. 7D. In the first time period T1 shown in FIG. 8, DY1 refers to the signal applied to the scan lines to trigger the sub-pixels shown in the first left column of the sub-pixels; in other word, DY1 refers to the signal applied to the scan lines to trigger the sub-pixels shown in the first upper row UR1 of the one group shown in FIG. 7A. In the first time period T1 shown in FIG. 8, DY2 refers to the signal applied to the scan lines to trigger the sub-pixels shown in the second left column of the sub-pixels; in other word, DY2 refers to the signal applied to the scan lines to trigger the sub-pixels shown in the second upper row UR2 of the one group shown in FIG. 7A. In the first time period T1 shown in FIG. 8, DY3 refers to the signal applied to the scan lines to trigger the sub-pixels shown in the third left column of the sub-pixels; in other word, DY3 refers to the signal applied to the scan lines to trigger the sub-pixels shown in the third upper row UR3 of the one group shown in FIG. 7A. And, in the first time period T1 shown in FIG. 8, DY4 refers to the signal applied to the scan lines to trigger the sub-pixels shown in the first right column of the sub-pixels; in other word, DY4 refers to the signal applied to the scan lines to trigger the sub-pixels shown in the fourth upper row UR4 of the one group shown in FIG. 7A. In addition, in the first time period T1 show in FIG. 8, SY1 refers to the signal applied to the scan lines to trigger the light sensor shown in the first left column of the light sensors; in other word, SY1 refers to the signal applied to the scan lines to trigger the light sensors shown in the first lower row LR1 of the one group shown in FIG. 7A. In the first time period T1 show in FIG. 8, SY2 refers to the signal applied to the scan lines to trigger the light sensor shown in the second left column of the light sensors; in other word, SY2 refers to the signal applied to the scan lines to trigger the light sensors shown in the second lower row LR2 of the one group shown in FIG. 7A. In the first time period T1 show in FIG. 8, SY3 refers to the signal applied to the scan lines to trigger the light sensor shown in the third left column of the light sensors; in other word, SY3 refers to the signal applied to the scan lines to trigger the light sensors shown in the third lower row LR3 of the one group shown in FIG. 7A. And, in the first time period T1 show in FIG. 8, SY4 refers to the signal applied to the scan lines to trigger the light sensor shown in the first right column of the light sensors; in other word, SY4 refers to the signal applied to the scan lines to trigger the light sensors shown in the fourth lower row LR4 of the one group shown in FIG. 7A. The signals shown in DY1, DY2, DY3, DY4, SY1, SY2, SY3 and SY4 in the second time period T2, the third time period T3 and the fourth time period T4 are similar to those illustrated for the first time period T1, and the descriptions related thereto are not repeated again.

The method for sensing a signal from a subject of the present embodiment is similar to the method illustrated in Embodiment 2, except for the following differences.

In the present embodiment, the display device further comprises a color filter layer comprising plural color units is disposed on the light sensors 121, and the color filter layer comprises plural first color units 1211, plural second color units 1221 and plural third color units 1231 which are respectively disposed on and corresponds to the light sensors 121. Herein, a color of the first color units 1211 is the same as a color of the sub-pixels 111 (i.e. first color sub-pixels), a color of the second color units 1221 is the same as a color of the sub-pixels 112 (i.e. second color sub-pixels), and a color of the third color units 1231 is the same as a color of the sub-pixels 113 (i.e. a third color sub-pixels). For example, the color of the first color unit 1211 and the sub-pixel 111 is red, the color of the second color unit 1221 and the sub-pixel 112 is green, and the color of the third color unit 1231 and the sub-pixel 113 is blue. In addition, the first color unit 1211, the second color unit 1221 and the third color unit 1231 are respectively adjacent to one pixel including the sub-pixels 111, 112, 113.

As shown in FIG. 7A to FIG. 7D and FIG. 8, when anyone of the light sensors 121 detects a signal from a subject, the first block B1 comprising four pixels and four light sensors is in enabled status in a first period time T1, wherein the sub-pixel 111 (which is red) is in enabled status and the light sensor 121 corresponding to the first color unit 1211 (which is red) adjacent to the sub-pixel 111 is also in enabled status; thus, a color of one of the plural color units (for example, the first color unit 1211) comprised in the first block B1 is the same as a color of the one of the plural sub-pixels (for example, the sub-pixel 111) comprised in the first block B1 which is in enabled status in the first time period T1. However, the sub-pixels 112, 113 adjacent to the light sensor 121 corresponding to the first color unit 1211 are in disabled status. In addition, the sub-pixel 112 (which is green) is in enabled status and the light sensor 121 corresponding to the second color unit 1221 (which is green) adjacent to the sub-pixel 112 is also in enabled status, but the sub-pixels 111, 113 adjacent to the light sensor 121 corresponding to the second color unit 1221 is in disabled status. Furthermore, the sub-pixel 113 (which is blue) is in enabled status and the light sensor 121 corresponding to the third color unit 1231 (which is blue) adjacent to the sub-pixel 113 is also in enabled status, but the sub-pixels 112, 113 adjacent to the light sensor 121 corresponding to the third color unit 1231 is in disabled status. Thus, adjacent two of the plural color units (for example, the first color unit 1211 and the second color unit 1221) are respectively disposed on adjacent two of the plural light sensors 121, the adjacent two of the plural light sensors 121 are in enabled status in the first time period T1, and the adjacent two of the plural color units (for example, the first color unit 1211 and the second color unit 1221) have different color.

Hence, as shown in FIG. 7A and FIG. 8, in the first time period T1, the first color sub-pixel (i.e. the sub-pixel 111) and the light sensor corresponding to the first color unit adjacent to the first color sub-pixel are in enabled status, the second color sub-pixel (i.e. the sub-pixel 112) and the sensor corresponding to the second color unit adjacent to the second color sub-pixel are in enabled status, and/or the third color sub-pixel (i.e. the sub-pixel 113) and the sensor corresponding to the third color unit adjacent to the third color sub-pixel are in enabled status. Hence, the second color sub-pixel and the third color sub-pixel with different color from the color of the first color unit are in disabled status, so the light sensor corresponding to the first color unit does not detect the light emitting from the second color sub-pixel and the third color sub-pixel. Similarly, the first color sub-pixel and the third color sub-pixel with different color from the color of the second color unit are in disabled status, so the light sensor corresponding to the second color unit does not detect the light emitting from the first color sub-pixel and the third color sub-pixel. The second color sub-pixel and the first color sub-pixel with different color from the color of the third color unit are in disabled status, so the light sensor corresponding to the third color unit does not detect the light emitting from the second color sub-pixel and the first color sub-pixel.

In addition, as shown in FIG. 7B and FIG. 8, the second block B2 comprising four pixels and four light sensors is in enabled status in a second period time T2. The enabling and the disabling of the sub-pixels and the sensors are similar to those for the first block B1, and are not illustrated again. As shown in FIG. 7C and FIG. 8, the third block B3 comprising four pixels and four light sensors is in enabled status in a third period time T3. The enabling and the disabling of the sub-pixels and the sensors are similar to those for the first block B1, and are not illustrated again. Furthermore, as shown in FIG. 7D and FIG. 8, the fourth block B4 comprising four pixels and four light sensors is in enabled status in a fourth period time T4. The enabling and the disabling of the sub-pixels and the sensors are similar to those for the first block B1, and are not illustrated again.

When the display device is used to sense a signal from a subject, the image resolution can further be improved by using the color filter layer corresponding to the light sensors in the display device and using the scanning method of the present embodiment.

In the aforesaid Embodiments 2 to 3, in one of the time periods, the sub-pixels and the light sensors to be enabled are in enabled status at the same time. However, the present disclosure is not limited thereto. In another embodiment, in one of the time periods, the sub-pixels to be enabled are in enabled status first, and then the light sensors to be enabled are in enabled status; and vice versa.

### Embodiment 4

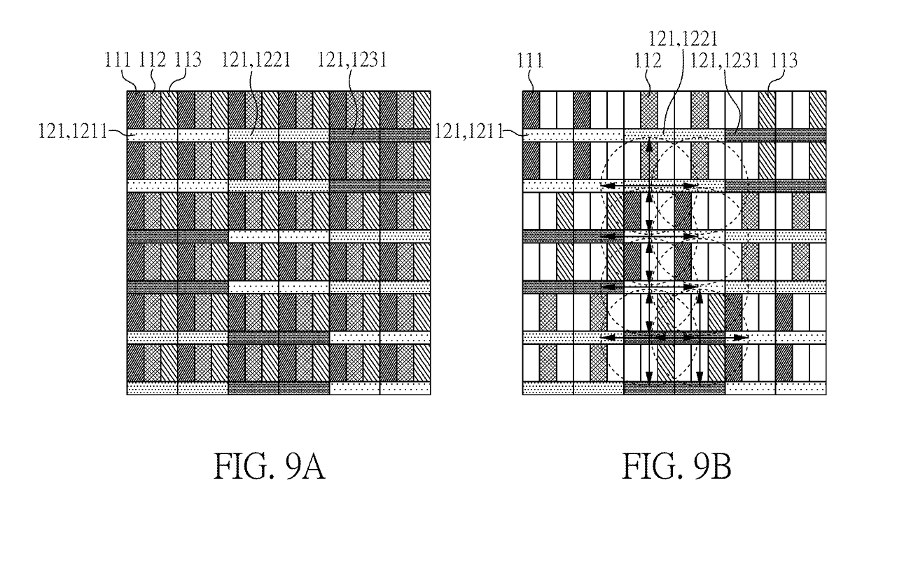

FIG. 9A is diagram illustrating sub-pixels and light sensors in a display device according to the present embodiment, which shows the arrangement of the pixels and the color units of the display device, and the filling patterns in the pixels and the color units are not referred to the enabling or disabling of the pixels and the light sensors. FIG. 9B is a diagram illustrating at least part of sub-pixels and light sensors which are in enabled status in a display device according to the present embodiment, wherein the at least part of sub-pixels and the light sensors which are in enabled status are present with filling patterns, and the sub-pixels and the light sensors which are in disabled status are present with blank.

The display device of the present embodiment is similar to that illustrated in Embodiment 3, except for the following differences.

In the present embodiment, when anyone of the light sensors 121 detects a signal from a subject, all the plural light sensors 121 are in enabled status and at least part of the plural sub-pixels 111, 112, 113 are in enabled status. More specifically, in the present embodiment, all the light sensors 121 corresponding to the first color units 1211, the second color units 1221 and the third color units 1231 are in enabled status; but only the sub-pixels adjacent to the first color units 1211, the second color units 1221 and the third color units 1231 and having the same color as the first color units 1211, the second color units 1221 and the third color units 1231 are in enabled status. For example, the light sensors 121 corresponding to the first color units 1211 are in enabled status, the sub-pixels 111 adjacent to the first color units 1211 are in enabled status, and the sub-pixels 112, 113 adjacent to the first color units 1211 are in disabled status. The light sensors 121 corresponding to the second color units 1221 are in enabled status, the sub-pixels 112 adjacent to the second color units 1221 are in enabled status, and the sub-pixels 111, 113 adjacent to the second color units 1221 are in disabled status. Similarly, the light sensors 121 corresponding to the third color units 1231 are in enabled status, the sub-pixels 113 adjacent to the third color units 1231 are in enabled status, and the sub-pixels 111, 112 adjacent to the third color units 1231 are in disabled status.

Hence, the sub-pixels with different color from a color of the color unit adjacent thereto are in disabled status, so the light sensor corresponding to the color unit does not detect the light emitting from the sub-pixel with different color from the color of the color unit adjacent thereto. Thus, the image resolution can further be improved.

In the present embodiment, one of the first color units 1211 is disposed between the second color unit 1221 and another one of the first color units 1211. However, the present disclosure is not limited thereto.

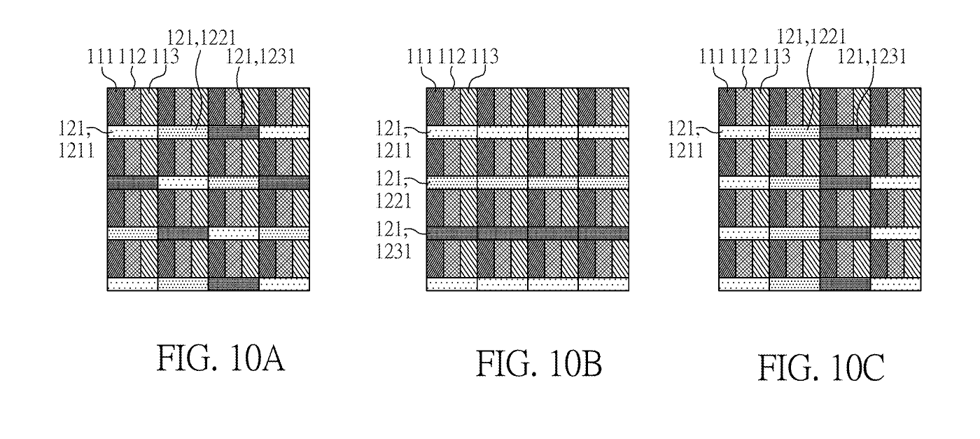

FIG. 10A to FIG. 10C are diagrams illustrating sub-pixels and light sensors in a display device according to different aspects of the present disclosure which shows the arrangement of the pixels and the color units of the display device, and the filling patterns in the pixels and the color units are not referred to the enabling or disabling of the pixels and the light sensors.

As shown in FIG. 10A, the first color unit 1211, the second color unit 1221 and the third color unit 1231 are arranged one by one. For example, the second color unit 1221 with a color different from the colors of the first color unit 1211 and the third color unit 1231 is disposed between the first color unit 1211 and the third color unit 1231.

As shown in FIG. 10B, the first color units 1211, the second color units 1221 and the third color units 1231 are respectively arranged in a row. As shown in FIG. 7C, the first color units 1211, the second color units 1221 and the third color units 1231 are respectively arranged in a column. Hence, for example, the first color units 1211 with the same color are arranged in a row or a column direction.

In the aforesaid embodiments, the light sensors can be disposed on a bottom substrate of the display device to obtain an in-cell image sensing display device; the light sensors can be disposed between a display medium layer and a protection substrate of the display device obtain an on-cell image sensing display device; or the light sensors can be disposed outside the protection substrate of the display device to obtain an out-cell image sensing display device. In addition, in the other embodiments of the present disclosure, the light sensors can at least partially overlap the pixels or the sub-pixels.

In Embodiments 3 and 4, the color filter layer corresponding to the light sensors can be integrated with a color filter layer corresponding to the pixels; or the color filter layer corresponding to the light sensors can be separated from the color filter layer corresponding to the pixels.

In the aforesaid embodiments, when the sub-pixel is smaller than light sensor, it is possible by rendering plural sub-pixels into a group to match the size of the light sensor.

In Embodiments 3 and 4, when the sub-pixel is larger than the light sensor, plural light sensors can be rendered into a group to match the size of the sub-pixel.

Even when the sizes of the sub-pixels and the light sensors do not well match (for example, the border of the block located in the middle of the sub-pixels or the light sensors), the size and the shape of the blocks do not need to be uniform, and the border line of the block can be adjusted.

In the aforesaid embodiment, the display device comprises display medium layer, which may comprises liquid crystals (LCs), quantum dots (QDs), fluorescence molecules, phosphors, organic light-emitting diodes (OLEDs), inorganic light-emitting diodes (LEDs), mini light-emitting diodes (mini-LEDs), micro light-emitting diodes (micro-LEDs), or quantum-dot light-emitting diodes (QLEDs). It could be understood that the chip size of the LED can be 300 μm to 10 mm, the chip size of the mini-LED can be 100 μm to 300 μm, and the chip size of the micro-LED can be 1 μm to 100 μm. But the present disclosure is not limited thereto.

In the present disclosure, at least two display devices can be arranged in juxtaposition to form a tiled display device. The at least two display devices can be the same or different.

The light sensors used in the above embodiments can be a tough sensor, a fingerprint sensor, an iris sensor, a retina sensor, a facial sensor, a vein sensor, a voice sensor, a motion sensor, a gesture sensor, or a DNA sensor. When the light sensors are not touch sensors, the display device made as described in any of the embodiments of the present disclosure as described previously can be co-used with a touch panel to form a touch display device. Meanwhile, a display device or touch display device may be applied to any electronic devices known in the art that need a display screen, such as displays, mobile phones, laptops, video cameras, still cameras, music players, mobile navigators, TV sets, and other electronic devices that display images.

Although the present disclosure has been explained in relation to its embodiment, it is to be understood that many other possible modifications and variations can be made without departing from the spirit and scope of the disclosure as hereinafter claimed.

What is claimed is:

1. A detecting method, comprising following steps:
providing a display device comprising a first block and a second block, wherein the first block and the second block respectively comprise at least one light sensor and plural sub-pixels, one of the at least one light sensor corresponds to at least two adjacent of the plural sub-pixels; and
detecting a signal from a subject, wherein one of the plural sub-pixels of the first block and the one of the at least one light sensor of the first block are in enabled status and the second block is in disabled status in a first time period, and one of the plural sub-pixels of the second block and the one of the at least one light sensor of the second block are in enabled status and the first block is in disabled status in a second time period.

2. The detecting method of claim 1, wherein a frame comprises N time periods comprising the first time period and the second time period, and N is an integer ranged from 2 to 50.

3. The detecting method of claim 2, wherein the display device further comprises a group, the group comprises M blocks comprising the first block and the second block, and M is an integer ranged from 2 to 50 and equal to N; wherein the first block is in enabled status and the rest of the blocks are in disabled status in the first time period while the second block is in enabled status and the rest of the blocks are in disabled status in the second time period.

4. The detecting method of claim 2, wherein the first block and the second block respectively further comprise a pixel comprising the plural sub-pixels, the pixel of the first block and the one of the at least one light sensor of the first block are in enabled status in the first time period, and the pixel of the second block and the one of the at least one light sensor of the second block are in enabled status in the second time period.

5. The detecting method of claim 2, wherein the first block and the second block respectively further comprise four pixels comprising the plural sub-pixels, the four pixels of the first block and four of the at least one light sensor of the first block of the first block are in enabled status in the first time period, and the four pixels of the second block and four of the at least one light sensor of the second block are in enabled status in the second time period.

6. The detecting method of claim 1, wherein the one of the plural sub-pixels of the first block and the one of the at least one of the plural light sensors of the first block are neighboring and in enabled status in the first time period, and the one of the plural sub-pixels of the second block and the one of the at least one of the plural light sensors of the second block are neighboring and in enabled status in the second time period.

7. The detecting method of claim 1, wherein another one of the plural light sensors of the first block which is in disabled status in the first time period is disposed between the one of the plural sub-pixels of the first block and the one of the at least one of the plural light sensors of the first block which are in enabled status in the first time period.

8. The detecting method of claim 1, wherein another one of the plural light sensor of the second block which is in disabled status in the second time period is disposed between the one of the plural sub-pixels and the one of the at least one of the plural light sensors which are in enabled status in the second time period of the second block.

9. The detecting method of claim 1, wherein the first block further comprises plural color units; wherein a color of one of the plural color units of the first block is the same as a color of the one of the plural sub-pixels which is in enabled status in the first time period of the first block.

10. The detecting method of claim 9, wherein adjacent two of the plural color units of the first block are respectively disposed on adjacent two of the plural light sensors of the first block, the adjacent two of the plural light sensors are in enabled status in the first time period, and the adjacent two of the plural color units have different color.

11. A detecting method, comprising following steps:
providing a display device comprising a display region, wherein plural sub-pixels and plural light sensors are disposed on the display region, and plural color units are respectively disposed on the plural light sensors; and
detecting a signal from a subject, wherein all the plural light sensors are in enabled status and one of the plural sub-pixels are in enabled status.

12. The detecting method of claim 11, wherein one of the plural light sensors corresponds to at least two adjacent of the plural sub-pixels.

13. The detecting method of claim 11, wherein the plural color units comprises two first color units and a second color unit adjacently disposed, one of the first color units is disposed between the second color unit and the other of the first color units, and a color of the first color units is different from a color of the second color unit.

14. The detecting method of claim 13, wherein the plural sub-pixels are disposed on a part of the display region, the plural sub-pixels which are in enabled status comprise two first color sub-pixels and a second color sub-pixel, the first color sub-pixels are respectively adjacent to the first color units and the second color sub-pixel is adjacent to the second color unit, a color of the first color sub-pixels is the same as a color of the first color units and a color of the second color sub-pixel is the same as a color of the second color unit.

15. The detecting method of claim 11, wherein the plural color units comprises a first color unit, a second color unit and a third color unit adjacently disposed, the second color unit is disposed between the first color unit and the third color unit, and colors of the first color unit, the second color unit and the third color unit are different.

16. The detecting method of claim 15, wherein the plural sub-pixels are disposed on a part of the display region, the plural sub-pixels which are in enabled status comprise a first color sub-pixel, a second color sub-pixel and a third color sub-pixel, the first color sub-pixel which is in enabled status is adjacent to the first color unit, the second color sub-pixel which is in enabled status is adjacent to the second color unit, the third color sub-pixel which is in enabled status is adjacent to the third color unit, and colors of the first color unit, the second color unit and the third color unit are different.

17. A display device comprising a display region, wherein the display device comprises:
plural sub-pixels disposed on the display region; and
plural light sensors disposed on the display region, wherein one of the plural light sensors corresponds to at least two adjacent of the plural sub-pixels.

18. The display device of claim 17, further comprising:
plural color units disposed on the plural light sensors and respectively corresponding to the plural light sensors, wherein the color units comprises a first color unit and a second color unit, and a color of the first color unit is different form a color of the second color unit.

19. The display device of claim 18, wherein the plural color units comprises two first color units and a second color unit adjacently disposed one of the first color units is disposed between the second color unit and the other of the first color units, and a color of the first color units is different from a color of the second color unit.

20. The display device of claim 18, wherein the plural color units comprises a first color unit, a second color unit and a third color unit adjacently disposed, the second color unit is disposed between the first color unit and the third color unit, and colors of the first color unit, the second color unit and the third color unit are different.
